(19) United States
(12) Patent Application Publication
(10) Pub. No.: US 2011/0070745 A1
(43) Pub. Date: Mar. 24, 2011

(54) POLISHING METHOD, POLISHING APPARATUS, AND MANUFACTURING METHOD OF SEMICONDUCTOR DEVICE

(76) Inventors: Yukiteru MATSUI, Kanagawa (JP); Satoko Seta, Tokyo (JP); Takatoshi Ono, Oita (JP); Hajime Eda, Kanagawa (JP)

(21) Appl. No.: 12/775,423

(22) Filed: May 6, 2010

(30) Foreign Application Priority Data
Sep. 24, 2009 (JP) 2009-219331

(51) Int. Cl. H01L 21/3105; B24B 1/00; B24B 41/06

(52) U.S. Cl. 438/759; 451/36; 451/364; 257/E21.244

(57) ABSTRACT

A polishing method includes performing conditioning process of injecting a conditioning agent onto a surface of a non-foam polishing pad arranged on a polishing table at a predetermined pressure, and polishing a surface of a polishing target while supplying a polishing slurry containing oxide particles and a surfactant onto the polishing pad, wherein an average of a residual cerium amount is equal to or smaller than 0.35 at % when a plurality of measurement regions, each 200 μm□ in area including the surface of the polishing pad, in a cross section of the polishing pad are measured after the conditioning process.

### CROSS-REFERENCE TO RELATED APPLICATIONS

This application is based upon and claims the benefit of priority from the prior Japanese Patent Application No. 2009-219331, filed on Sep. 24, 2009; the entire contents of which are incorporated herein by reference.

### BACKGROUND OF THE INVENTION

1. Field of the Invention

The present invention relates to a polishing method, a polishing apparatus, and a manufacturing method of a semiconductor device.

2. Description of the Related Art

In recent years, as a planarization technique used in a manufacturing process of a semiconductor device, a Chemical Mechanical Polishing (CMP) method has become a mainstream. The CMP process of a silicon dioxide film is used for forming a Shallow Trench Isolation (STI), planarizing a Pre Metal Dielectric (PMD), and the like, and is essential for device manufacturing, so that the CMP process is extremely important in the manufacturing process of the semiconductor device.

Cerium oxide particles have extremely high polishing rate with respect to the silicon dioxide film. When a surfactant is added to the cerium oxide particles and the surfactant adsorbs onto the surface of the cerium oxide particles, an adsorbed state changes depending on a polishing load and a load dependency of the polishing rate increases. Consequently, a selectivity of the polishing rate with respect to a concave-convex portion of a polishing target film improves, enabling to obtain high flatness. Therefore, in the CMP process of the silicon dioxide film, a polishing solution containing the cerium oxide particles and the surfactant is widely used (for example, see Japanese Patent Application Laid-open No. 2001-9702).

In the CMP process in which the polishing solution containing the cerium oxide particles and the surfactant is used to use a mechanism of planarization by utilizing a change in a particle agglomeration state by a load in this manner, there is a risk of increasing scratches due to particle agglomeration. The scratches generated after this CMP process, particularly, the scratches generated after the CMP process of the silicon dioxide film for the STI formation are a factor in degrading the yield (for example, see Japanese Patent Application Laid-open No. 2006-278977). The mechanism of scratch generation in the CMP process of the silicon dioxide film is still unknown, however, this problem becomes remarkable with miniaturization of a pattern and improvement in performance of a device, and a demand for reducing a defect density such as the scratches after the CMP process has become extremely severe in recent years. Moreover, the demand for reducing the defect density such as the scratches after the CMP process is required not only for the silicon dioxide film after the CMP process but also for polishing target films in general to be processed in the CMP process.

### BRIEF SUMMARY OF THE INVENTION

A polishing method according to an embodiment of the present invention comprises: performing conditioning process of injecting a conditioning agent containing liquid onto a surface of a non-foam polishing pad arranged on a polishing table at a predetermined pressure; supplying a polishing slurry containing oxide particles and a surfactant onto the polishing pad; and polishing a surface of a polishing target by relatively sliding the polishing target and the polishing pad; wherein an average of a residual cerium amount is equal to or smaller than 0.35 at % when a plurality of measurement regions, each 200 μm□ in area including the surface of the polishing pad, in a cross section of the polishing pad are measured after the conditioning process.

A polishing apparatus according to an embodiment of the present invention comprises: a polishing table; a non-foam polishing pad arranged on the polishing table; a polishing head that holds a polishing target so that a polishing target surface of the polishing target is opposed to a side of the polishing pad; a chemical supplying unit that supplies a polishing slurry containing oxide particles and a surfactant onto the polishing pad at a time of polishing while pressing the polishing target surface of the polishing target held by the polishing head against the polishing pad and relatively sliding the polishing target held by the polishing head and the polishing table; a dresser that grinds a surface of the polishing pad; and a conditioning agent injecting unit that injects a conditioning agent containing liquid onto the surface of the non-foam polishing pad at a predetermined pressure.

### BRIEF DESCRIPTION OF THE DRAWINGS

FIG. 1 is a side view schematically illustrating a configuration of a typical CMP apparatus;

FIG. 2 is a cross-sectional view schematically illustrating a state of a typical polishing pad at the time of polishing;

FIG. 3 is a diagram schematically illustrating an estimated mechanism of scratch generation;

FIG. 4 is a cross-sectional view of the polishing pad for schematically illustrating regions on which a quantitative analysis is performed;

FIG. 5 is a diagram illustrating a relationship between the number of residual abrasive grains on a polishing pad surface and the number of scratches on a polishing target surface;

FIG. 6A is a side view of a CMP apparatus according to an embodiment;

FIG. 6B is a plan view of the CMP apparatus according to the embodiment;

FIG. 7 is a diagram illustrating experiment conditions and measurement results in Examples 1 to 4; and

FIG. 8 is a diagram illustrating experiment conditions and measurement results in Comparison Examples 1 to 4.

### DETAILED DESCRIPTION OF THE INVENTION

A polishing method, a polishing apparatus, and a manufacturing method of a semiconductor device according to embodiments of the present invention are explained below in detail with reference to the accompanying drawings. The present invention is not limited to this embodiment.

In the following, first, a mechanism of scratch generation at the time of a CMP process is estimated, and a polishing method and a manufacturing method of a semiconductor device according to the embodiment of the present invention capable of reducing generation of scratches based on this mechanism are explained.

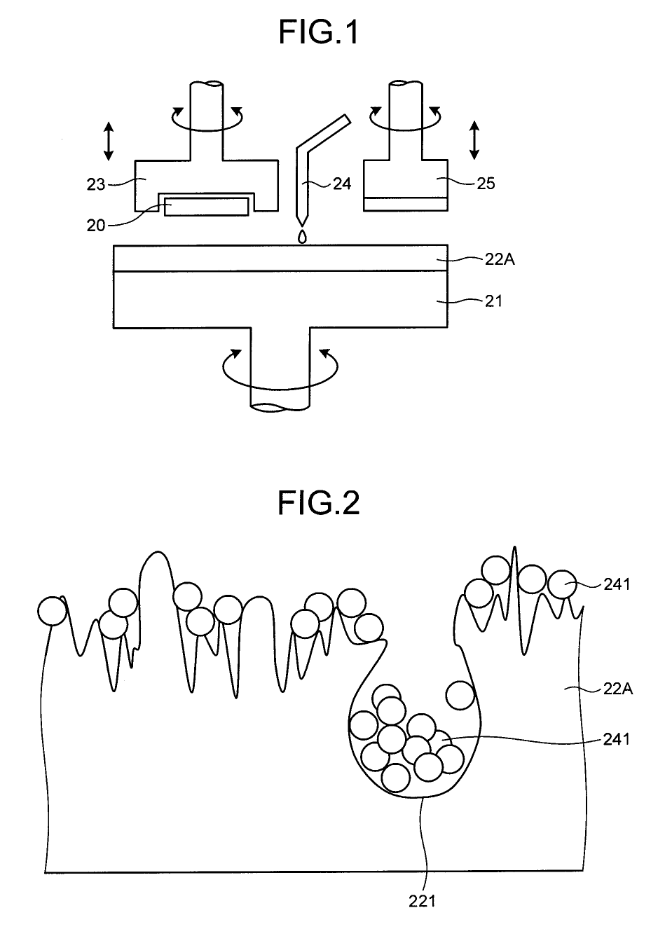

FIG. 1 is a side view schematically illustrating a configuration of a typical CMP apparatus. The CMP apparatus includes a rotatable polishing table 21, a foam polishing pad 22A that is arranged on the polishing table 21 and is made of a polyurethane resin or the like, a polishing head 23 that is arranged above the polishing pad 22A and holds a polishing target 20 such as a semiconductor substrate, a chemical supplying nozzle 24 for supplying chemical such as a polishing slurry at the time of polishing, and a dresser 25 that is arranged above the polishing pad 22A and is composed of, for example, a diamond disk and performs dressing on the polishing pad 22A.

The polishing head 23 holds the polishing target 20 by a unit such as a vacuum chuck holder so that a polishing target surface is opposed to the polishing pad 22A on the polishing table 21. The polishing head 23 and the dresser 25 are configured to be rotatable in the same plane as the polishing table 21 and movable in a direction perpendicular to the surface of the polishing table 21 so that the surfaces of the polishing head 23 and the dresser 25 can come into contact with the surface of the polishing pad 22A. Moreover, a polishing slurry supplying tank, although not shown, is connected to the chemical supplying nozzle 24.

A CMP process method using this CMP apparatus is schematically explained. As an example of the polishing target 20, a semiconductor substrate, on the whole surface of which a silicon dioxide film that fills a concave portion formed at a predetermined position of the surface is formed, is used. In this case, irregularities are formed on the surface of the silicon dioxide film to be the polishing target surface.

Before performing a polishing process, the semiconductor substrate is held by the polishing head 23 so that the silicon dioxide film is opposed to the polishing pad 22A, and the polishing slurry containing cerium oxide particles and a surfactant is supplied onto the polishing pad 22A from the chemical supplying nozzle 24. As the surfactant, for example, polycarboxylic acid as an anionic surfactant or its salt can be used. The cerium oxide particles as abrasive grains are coated with the anionic surfactant between the polishing pad 22A and the silicon dioxide film.

Next, the polishing head 23 is moved in a direction of the polishing table 21 to press the semiconductor substrate against the surface of the polishing pad 22A, and the polishing process is performed on the surface of the semiconductor substrate while rotating the polishing table 21 and the polishing head 23. FIG. 2 is a cross-sectional view schematically illustrating a state of a typical polishing pad at the time of the polishing. As shown in FIG. 2, a lot of agglomerated abrasive grains 241 in which the cerium oxide particles are agglomerated with the surfactant and swarf that are generated at the time of the polishing are accumulated in a foam portion on the surface of the polishing pad 22A or a concave portion 221, such as a groove portion and a dimple, formed on the surface of the polishing pad 22A. Consequently, clogging occurs in the polishing pad 22A and thus the polishing rate decreases. To solve this problem, a dressing process is performed.

The dressing process is a process of pressing the surface of the dresser 25 against the surface of the polishing pad 22A, grinding the surface of the polishing pad 22A while rotating the polishing table 21 and the dresser 25, and removing the agglomerated abrasive grains and the swarf on the surface of the polishing pad 22A and performing dressing. In this manner, in the CMP process, the polishing process and the dressing process are performed.

In the above process procedure, when the cross section of the polishing pad 22A after the semiconductor substrate is polished is analyzed by using the Scanning Electron Microscope and Energy Dispersive X-ray Spectroscopy (SEM-EDX), specially, a lot of cerium (CE) elements are detected in the concave portion 221 on the surface of the polishing pad 22A. As described above, this is considered to be because of the accumulation of the agglomerated abrasive grains 241 in the concave portion 221 on the surface of the polishing pad 22A as shown in FIG. 2 due to the use of the foam polishing pad 22A. When the polishing slurry containing the cerium oxide particles and the surfactant is used, the agglomerated abrasive grains 241 are generated by the surfactant having a high agglomeration effect adsorbing onto the surface of the cerium oxide particles.

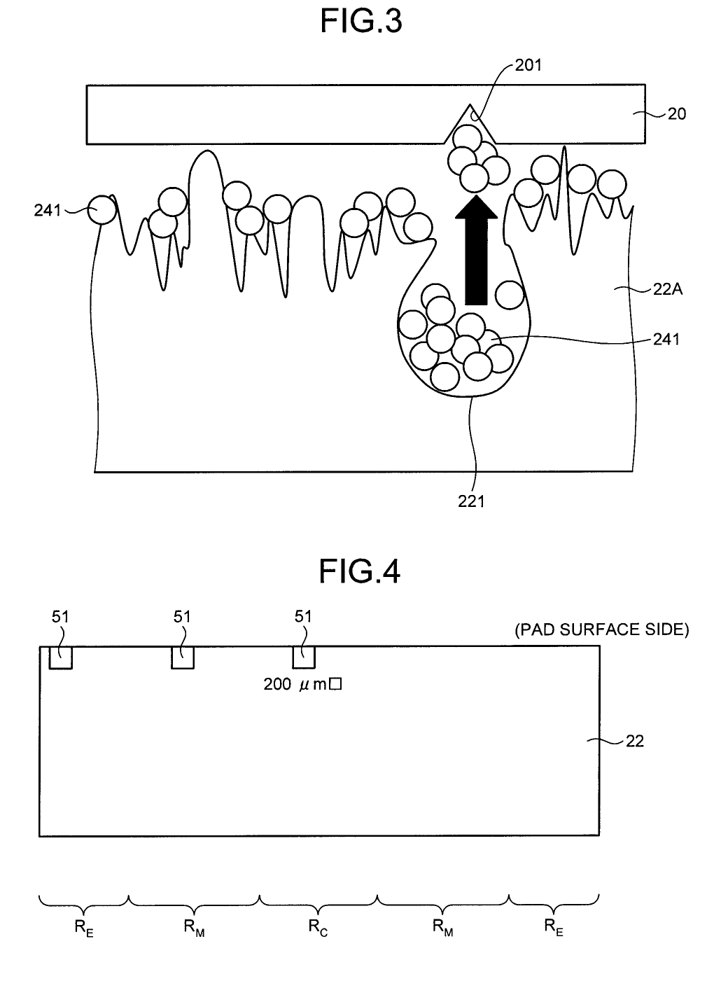

FIG. 3 is a diagram schematically illustrating an estimated mechanism of the scratch generation. According to the above analysis result, it is considered that the agglomerated abrasive grains 241 accumulated in the concave portion 221 of the foam polishing pad 22A refloat to the surface by the pressure from the polishing head 23 at the time of the polishing process and a scratch 201 is induced on the surface of the polishing target 20 by performing the polishing process in this state. This phenomenon of generating the scratch 201 tends to occur when the content of the surfactant in the polishing slurry with the cerium oxide particles as polishing particles is 0.5 wt % or more.

When the scratch 201 is considered to be generated by such a mechanism, removal of the agglomerated abrasive grains 241 accumulated in the surface of the polishing pad 22A is considered to be effective to reduce the scratches 201. As described above, typically, the surface of the polishing pad 22A is grinded in the dressing process, however, the generation of the scratches 201 cannot be suppressed by such a method. This is considered to be because of the difficulty in removing the agglomerated abrasive grains 241 that are trapped in the concave portion 221 of the foam portion (pore) formed in the polishing pad 22A by the typical dressing process using a diamond disk. Therefore, a process for suppressing the generation of the scratches 201 other than the typical dressing process is required.

Thus, the inventors used a non-foam polishing pad as the polishing pad and studied a relationship between residual abrasive grain amount on the polishing pad surface and the number of the scratches on the polishing target surface after performing the CMP process by using the polishing pad through experiments. FIG. 4 is a cross-sectional view of the polishing pad for schematically illustrating regions on which a quantitative analysis is performed. FIG. 4 illustrates the cross section including the diameter of a polishing pad 22 is shown. In FIG. 4, a center portion R_{C} is a predetermined region including the center of the polishing pad 22, an edge portion R_{E} is a predetermined region around the peripheral portion of the polishing pad 22, and a middle portion R_{M} is a region between the center portion R_{C} and the edge portion R_{E}. The quantitative analysis is performed at nine measurement regions 51 in total, i.e., three points in the center portion R_{C}, three points in the edge portion R_{E}, and three points in the middle portion R_{M}, in the cross section of the polishing pad 22 by the SEM-EDX. As shown in FIG. 4, the measurement region 51 is a region of 200 μm□ including the surface of the polishing pad 22. Then, the average of the quantitative analysis results obtained at nine measurement regions 51 is calculated to calculate the residual cerium amount.

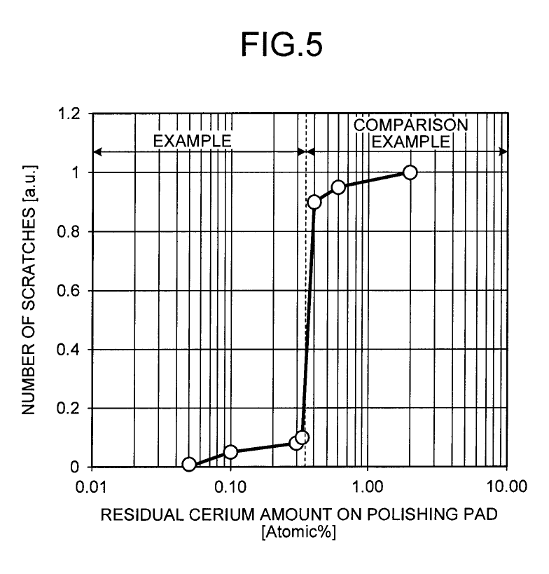

FIG. 5 is a diagram illustrating a relationship between the number of the residual abrasive grains on the polishing pad surface and the number of the scratches on the polishing target surface. In FIG. 5, the horizontal axis indicates the residual cerium amount (at %) on the polishing pad in a logarithmic scale and the vertical axis indicates the number of the scratches (arbitrary unit). Details of each sample in FIG. 5 are explained in the examples later.

As shown in FIG. 5, a correlation exists between the residual cerium amount on the polishing pad surface and the number of the scratches on the polishing target surface. Specifically, it is found that the number of the scratches on the polishing target surface decreases as the residual cerium amount (residual abrasive grain amount) on the polishing pad surface decreases. More specifically, when the residual cerium amount on the polishing pad surface is 0.35 at % or less, for example, the number of the scratches generated on the polishing target surface can be reduced to about 1/10 or less compared with the number of the scratches generated on the polishing target surface when the residual cerium amount on the polishing pad surface is 2 at %. Moreover, as a result of such an experimental result, the scratches can be considered to be generated with the above mechanism.

Therefore, in the present embodiment, the non-foam polishing pad is used as the polishing pad, a conditioning process of injecting a conditioning agent containing liquid onto the surface of the polishing pad is performed, and thereafter the polishing process is performed on the polishing target. Whereby, the residual cerium amount on the polishing pad surface after the conditioning process can be made 0.35 at % or less, enabling to reduce the number of the scratches on the polishing target surface compared with the conventional technology. The residual cerium amount on the polishing pad surface after the conditioning process is preferably measured by performing a composition analysis (e.g., SEM-EDX) at a plurality of points in each of the three portions of the center portion R_{C}, the middle portion R_{M}, and the edge portion R_{E} of the polishing pad and calculating the average thereof.

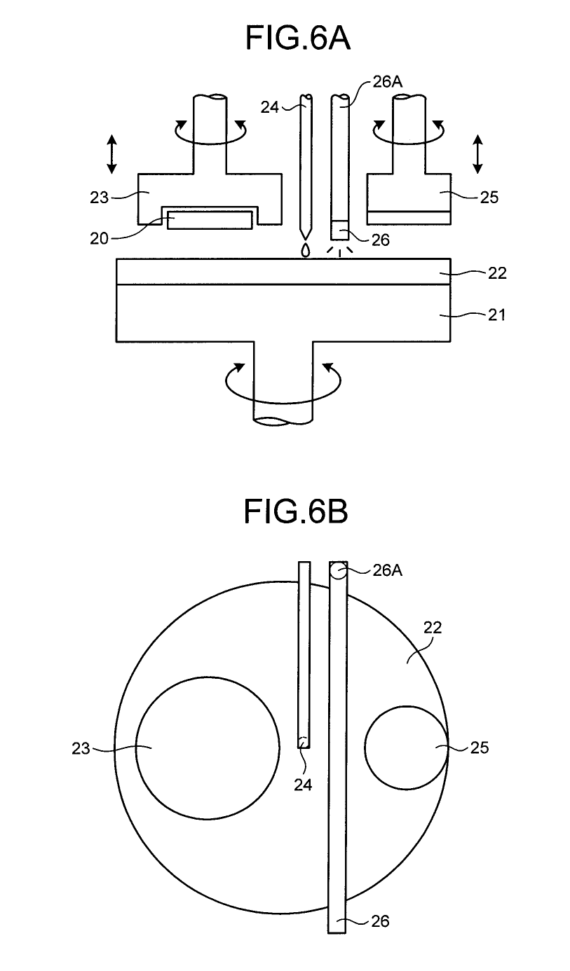

FIGS. 6A and 6B are diagrams schematically illustrating a configuration of the CMP apparatus to which the polishing method according to the present embodiment is applied, in which FIG. 6A is a side view of the CMP apparatus according to the present embodiment and FIG. 6B is a plan view of the CMP apparatus according to the present embodiment. In this CMP apparatus, the non-foam polishing pad 22 composed of a polymer such as polyurethane and polybutadiene is used as the polishing pad and a conditioning agent injection nozzle 26 for injecting the conditioning agent onto the polishing pad 22 at the time of the conditioning process is further included compared with the CMP apparatus shown in FIG. 1. This conditioning agent injection nozzle 26 having a tubular structure is arranged approximately above the middle of the polishing pad 22 to extend in the diametrical direction of the polishing pad 22 and has a plurality of holes for injecting the conditioning agent in a side opposing the polishing pad 22. Moreover, this conditioning agent injection nozzle 26 is connected to a not-shown conditioning agent supplying unit that supplies the conditioning agent onto the polishing pad 22 at a predetermined pressure via a connecting tube 26A. Components that are the same as those in the CMP apparatus shown in FIG. 1 are given the same reference numerals and explanation thereof is omitted.

The polishing method using this CMP apparatus is schematically explained. As an example of the polishing target 20, a semiconductor substrate, on the whole surface of which a silicon dioxide film that fills a concave portion formed at a predetermined position of the surface is formed, is used. In this case, irregularities are formed on the surface of the silicon dioxide film to be the polishing target surface.

Before performing the polishing process, the semiconductor substrate is held by the polishing head 23 so that the silicon dioxide film is opposed to the polishing pad 22, and the polishing slurry containing the cerium oxide particles and the surfactant is supplied onto the polishing pad 22 from the chemical supplying nozzle 24. As the surfactant, for example, polycarboxylic acid as the anionic surfactant or its salt can be used. The cerium oxide particles as the abrasive grains are coated with the anionic surfactant between the polishing pad 22 and the silicon dioxide film.

Next, the polishing head 23 is moved in the direction of the polishing table 21 to press the semiconductor substrate against the surface of the polishing pad 22, and the polishing process is performed on the surface of the semiconductor substrate (silicon dioxide film) while rotating and sliding the polishing table 21 and the polishing head 23. In the polishing process, the content of the cerium oxide particles in the polishing slurry is preferably 0.1 to 10 wt %. If the content is less than 0.1 wt %, the polishing rate tends to decrease, and if the content is more than 10 wt %, the number of the scratches generated on the surface of the silicon dioxide film may increase. Moreover, the content of the surfactant in the polishing slurry is preferably 0.001 to 5 wt %. If the content is less than 0.001 wt %, the load dependency on the polishing rate becomes small and a high flatness is difficult to obtain, and if the content is more than 5 wt %, decrease in polishing rate may become large.

After finishing the polishing process, the dressing process is performed on the polishing pad 22. As described above, in the dressing process, the surface of the dresser 25 is pressed against the surface of the polishing pad 22, the surface of the polishing pad 22 is grinded while rotating the polishing table 21 and the dresser 25, and the abrasive grains remaining on the surface of the polishing pad 22 are removed and the dressing is performed. Whereby, the polishing rate increases. Moreover, with this dressing process, the surface of the polishing pad 22 is adjusted so that the abrasive grains are held on the surface of the polishing pad 22.

Next, the conditioning process is performed. The conditioning process is a process of injecting the conditioning agent from the conditioning agent injection nozzle 26 at a predetermined pressure and removing the cerium oxide particles remaining on the surface of the polishing pad 22. Thereafter, the polishing process is performed again, and the above process is repeated.

In the above explanation, the conditioning process is performed after the dressing process, however, the conditioning process can be performed at the same time as the dressing process, or the dressing process can be performed after the conditioning process. Moreover, it is applicable that the dressing process is not performed every time the polishing process is performed. Furthermore, when the surface of the polishing target 20 is subjected to the CMP process for the first time, the polishing process is performed using a dummy semiconductor substrate, the dressing process and the conditioning process are performed on the polishing pad 22, and thereafter the semiconductor substrate to be used as a product is attached to the polishing head 23 to perform the CMP process.

As the conditioning agent used in the conditioning process, pure water, a solution containing the surfactant, such as a cationic surfactant, an anionic surfactant, an amphoteric surfactant, and a nonionic surfactant, with a high cleaning effect, a solution containing a hydrosoluble polymer with a high cleaning effect, or the like can be used. Moreover, a mixed fluid obtained by mixing inert gas, such as N₂ gas, Ar gas, and air, with any of the above liquids can be used. In this case, the mixed fluid can be injected onto the polishing pad 22 from the conditioning agent injection nozzle 26 in the form of a mist.

Examples of the cationic surfactant include aliphatic amine salt and aliphatic ammonium salt. Examples of the anionic surfactant include carboxylate, sulfonate, sulfate ester salt, and phosphate ester salt. Examples of the carboxylate include fatty acid soap and alkyl ether carboxylate. Examples of the sulfonate include alkyl benzene sulfonate, alkyl naphthalene sulfonate, and α-olefin sulfonate. Examples of the sulfate ester salt include higher alcohol sulfate ester salt, alkyl ether sulfate, and polyoxyethylene alkyl phenyl ether sulfate. Examples of the phosphate ester salt include alkyl phosphate ester salt. Among these, the sulfonate is preferable, the alkyl benzene sulfonate is more preferable, and ammonium dodecylbenzenesulfonate is particularly preferable.

Moreover, examples of the amphoteric surfactant include a betaine-type surfactant. Examples of the non-ionic surfactant include a polyethyleneglycol-type surfactant, acetylene glycol, ethylene oxide adduct of acetylene glycol, and acetylene alcohol. Furthermore, examples of the hydrosoluble polymer include an anionic polymer, a cationic polymer, an amphoteric polymer, and a nonionic polymer. Examples of the anionic polymer include polyacrylic acid and its salt, polymethacrylic acid and its salt, and polyvinyl alcohol. Examples of the cationic polymer include polyethylenimine and polyvinylpyrrolidone. Examples of the amphoteric polymer include polyacrylamide. Examples of the nonionic polymer include polyethylene oxide and polypropylene oxide.

The content of the surfactant or the hydrosoluble polymer in the solution used for the conditioning agent is preferably 1 wt % or less. This is because if the content of the surfactant or the hydrosoluble polymer is more than 1 wt %, the agglomeration effect has more influence than the cleaning effect. Moreover, the content of the surfactant or the hydrosoluble polymer is more preferably 0.001 to 0.5 wt %, and is further more preferably 0.01 to 0.1 wt % for obtaining more efficient cleaning effect. Furthermore, the anionic surfactant, the nonionic surfactant, or the hydrosoluble polymer is preferable in that the residual abrasive grains (agglomerated abrasive grains) on the surface of the polishing pad 22 can be efficiently removed. Moreover, as the type of the surfactant, the anionic surfactant with a benzene ring and a short alkyl chain is preferable in terms of the cleaning performance, particularly, as the surfactant, dodecylbenzenesulfonic acid or its salt such as ammonium dodecylbenzenesulfonate and potassium dodecylbenzenesulfonate is preferable, and a solution containing this at a concentration of 0.01 to 0.1 wt % is preferable.

Moreover, the supply flow rate of the conditioning agent onto the polishing pad 22 is preferably 0.5 mL/min to 100 L/min. This is because if the supply flow rate of the conditioning agent is less than 0.5 mL/min, the cleaning effect is generally insufficient, and if the supply flow rate of the conditioning agent is more than 100 L/min, the process cost for manufacturing the semiconductor device increases.

Furthermore, the supply pressure of the conditioning agent is preferably 500 to 5000 hPa. This is because if the supply pressure of the conditioning agent is less than 500 hPa, the cleaning effect is generally insufficient, and if the supply pressure of the conditioning agent is more than 5000 hPa, mechanical damage to the polishing pad 22 occurs. Particularly, the supply pressure of the conditioning agent is preferably 1000 to 3000 hPa. The supply pressure within this range can efficiently remove the cerium oxide particles agglomerated on the polishing pad 22 without causing the mechanical damage to the polishing pad 22.

Moreover, at the time of the conditioning process, the rotation speed of the polishing pad 22 (the polishing table 21) can be arbitrary set and is preferably set high within the range that can be realized by the CMP apparatus. This is because residues on the surface of the polishing pad 22 can be efficiently removed by the centrifugal force as the rotation speed of the polishing pad 22 increases.

Furthermore, the conditioning process is performed for 10 to 30 seconds under the process condition described above. The residual cerium amount on the polishing pad 22 can be reduced more as the time for this conditioning process becomes long, and consequently the number of the scratches on the surface of the polishing pad 22 can be reduced. However, the time for the conditioning process is preferably short in terms of shortening of the process time and the process cost. For example, when the rotation speed of the polishing pad 22 is set high, the supply flow rate of the conditioning agent is set large, or the supply pressure is set high, the time for the conditioning process can be made short. The time for this conditioning process is determined by experiment in advance so that the residual cerium amount on the surface of the polishing pad 22 polished under the set process condition is 0.35 at % or less described above.

In this manner, the non-foam polishing pad 22 is used, and the polishing process is performed after performing the conditioning process of injecting the conditioning agent at a predetermined pressure onto the surface of the polishing pad 22 from the conditioning agent injection nozzle 26. Whereby, the average of the residual cerium amount measured by the SEM-EDX or the like at a plurality of the regions, each 200 μm□ in area including the surface, in the cross section of the surface of the polishing pad 22 after the conditioning process, more preferably, the average of the residual cerium amount measured at a plurality of points in each of the regions of the center portion R_{C}, the middle portion R_{M}, and the edge portion R_{E} of the polishing pad 22, is controlled to be 0.35 at % or less. In other words, the polishing pad 22 does not have the foam portion, so that the agglomerated abrasive grains are not easily trapped on the surface of the polishing pad 22 and the amount of the agglomerated abrasive grains (cerium oxide) remaining on the surface of the polishing pad 22 that cause the scratches is reduced by the conditioning process before the polishing process, whereby it is possible to reduce the accumulation of the agglomerated abrasive grains on the surface of the polishing pad 22.

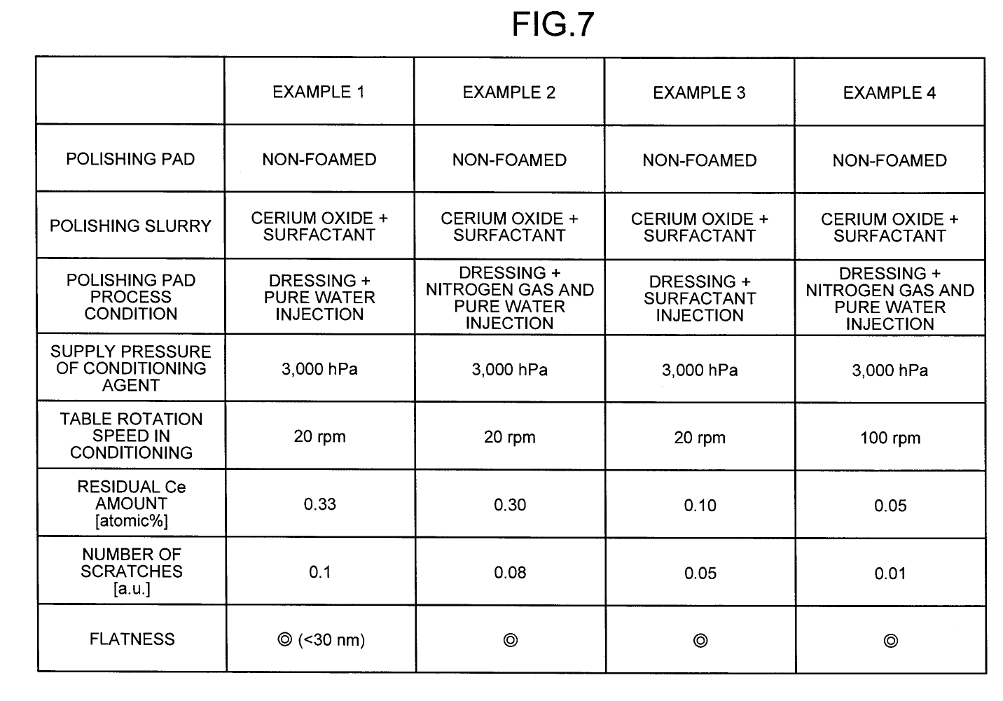

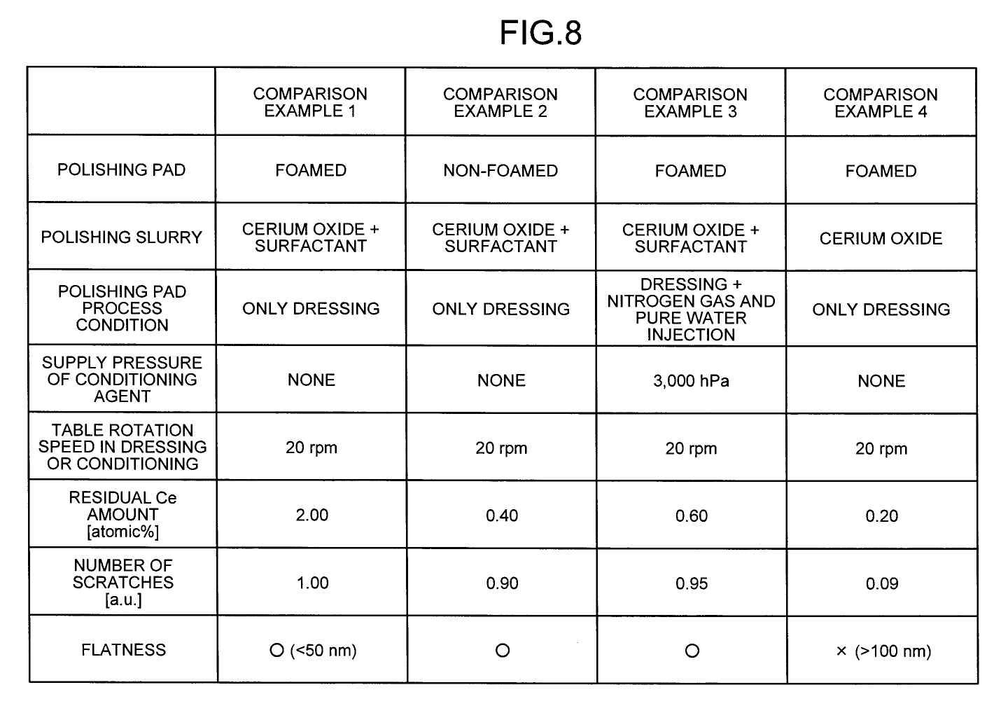

Explanation is given for examples according to the present embodiment below together with comparison examples. FIG. 7 is a diagram illustrating experiment conditions and measurement results in Examples 1 to 4. FIG. 8 is a diagram illustrating experiment conditions and measurement results in Comparison Examples 1 to 4.

### EXPERIMENTAL METHOD

### (CMP Apparatus and Polishing Pad)

In all of Examples and Comparison Examples, FREX300E (trade name) manufactured by Ebara Corporation is used as the CMP apparatus. As the polishing pad, in Examples 1 to 4 and Comparison Example 2, a non-foam polishing pad NCP-2 (trade name) manufactured by Nihon Micro Coating Co., Ltd. is used, and in Comparison Examples 1, 3, and 4, a foam polishing pad IC1000/Suba 400 (trade name) manufactured by Rohm and Haas Company is used.

### (Polishing Slurry)

As the polishing slurry, in Examples 1 to 4 and Comparison Examples 1 to 3, the polishing slurry containing the cerium oxide at a concentration of 0.5 wt % and the surfactant at a concentration of 1.0 wt % is used, and in Comparison Example 4, the polishing slurry containing the cerium oxide at a concentration of 0.5 wt % is used. As the cerium oxide that is the abrasive grain, DLS2 (trade name) manufactured by Hitachi Chemical Co., Ltd. is used, and as the surfactant, TK75 (trade name) that is composed of an ammonium polycarboxylate salt and is manufactured by Kao Corporation is used.

### (Process Condition of Polishing Pad)

In Example 1, after performing the dressing process, the conditioning process of injecting pure water used as the conditioning agent onto the polishing pad surface at a pressure of 3000 hPa is performed. In Examples 2 and 4 and Comparison Example 3, after performing the dressing process, the conditioning process of injecting a mixed fluid of pure water and nitrogen gas used as the conditioning agent onto the polishing pad surface at a pressure of 3000 hPa is performed. In Example 3, after performing the dressing process, the conditioning process of injecting a solution containing the surfactant as the conditioning agent at a pressure of 3000 hPa is performed. As the surfactant, ammonium dodecylbenzenesulfonate is used, and a solution in which the surfactant is contained in pure water at a concentration of 0.05 wt % is used. In Comparison Examples 1, 2, and 4, only the dressing process is performed and the conditioning process is not performed.

### (Rotation Speed of Polishing Table at the Time of Conditioning)

The rotation speed of the polishing table at the time of the conditioning (dressing) is 20 rpm in Examples 1 to 3 and Comparison Examples 1 to 4 and is 100 rpm in Example 4.

### (Experimental Method)

After attaching the polishing pad to the polishing table of the CMP apparatus and performing the dressing process, the polishing head is caused to hold a dummy wafer, and 24 dummy wafers are polished by using the above polishing slurry. Thereafter, the dressing process or the dressing process and the conditioning process is performed on a plurality of samples under each process condition of the polishing pad, and then the polishing head is caused to hold the silicon substrate on which the silicon dioxide film (SiO₂ film) is formed and the SiO₂ film is polished by using the polishing pads as other samples while performing the quantitative analysis on part of the plurality of samples.

### (Measurement of Number of Scratches and Flatness of Polishing Target and Measurement of Residual Cerium Amount on Polishing Pad)

The number of the scratches and the flatness of the SiO₂ film after the polishing are measured, for example, by using the SEM. The polishing pad after the conditioning process is subjected to an ion polishing to process a cross section, and the composition analysis (quantitative analysis) is performed by the SEM-EDX on three measurement regions 51 in each of the center portion R_{C}, the edge portion R_{E}, and the middle portion R_{M} of the polishing pad shown in FIG. 4. The measurement region 51 is the region of 200 μm□ including the surface. Then, the average of the quantitative analysis results at nine measurement regions 51 in total is calculated to calculate the residual cerium amount. The residual cerium amount used below indicates the average of a plurality of points.

### EXPERIMENT RESULT

In Comparison Example 1, the foam polishing pad is used, and after performing only the dressing process without performing the conditioning process, the SiO₂ film is polished. In this case, the residual cerium amount on the polishing pad is 2.00 at %. The number of the scratches formed on the SiO₂ film at this time is set to 1.00 as a reference with respect to Examples 1 to 4 and Comparison Examples 2 to 4. The number of the scratches in Comparison Example 1 is a value out of the allowable range in manufacturing the semiconductor device. The flatness of the SiO₂ film at this time is as good as less than 50 nm.

In Comparison Example 2, the non-foam polishing pad is used, and after performing only the dressing process without performing the conditioning process, the SiO₂ film is polished. In this case, the residual cerium amount on the polishing pad is 0.40 at % that is lower than the case of Comparison Example 1. However, the number of the scratches formed on the SiO₂ film at this time is 0.90. The flatness of the SiO₂ film at this time is as good as less than 50 nm similarly to Comparison Example 1.

According to Comparison Examples 1 and 2, in the case of using the non-foam polishing pad, the residual cerium amount can be reduced compared with the case of using the foam polishing pad, however, the number of the scratches on the SiO₂ film after the polishing process cannot be reduced greatly. In other words, only changing the foam polishing pad to the non-foam polishing pad is insufficient to reduce the number of the scratches on the SiO₂ film after the polishing process. Moreover, the number of the scratches on the SiO₂ film cannot be reduced only by the dressing process.

In Comparison Example 3, the foam polishing pad is used, and after performing the dressing process and the conditioning process by injecting a mixed fluid of nitrogen gas and pure water onto the polishing pad surface, the SiO₂ film is polished. In this case, the residual cerium amount on the polishing pad is 0.60 at % that is lower than the case of Comparison Example 1 but is higher than the case of Comparison Example 2. Therefore, the number of the scratches formed on the SiO₂ film and the flatness of the SiO₂ film are similar to Comparison Examples 1 and 2.

According to Comparison Example 3, even if the conditioning process is performed after performing the dressing process on the foam polishing pad, the number of the scratches after the subsequent polishing process on the SiO₂ film cannot be reduced. This is considered to be because of the accumulation of the agglomerated abrasive grains in the concave portion, such as the foam portion, of the polishing pad. In other words, even if the conditioning process is performed on the foam polishing pad, the agglomerated abrasive grains in the concave portion of the polishing pad cannot be removed.

In Comparison Example 4, the foam polishing pad is used, and after performing the dressing process without performing the conditioning process, the polishing process of the SiO₂ film is performed by using the polishing slurry containing only the cerium oxide particles. In this case, the residual cerium amount on the polishing pad can be reduced to 0.20 at %. Consequently, the number of the scratches on the SiO₂ film becomes 0.09. This is considered to be because the agglomeration effect of the cerium oxide particles is suppressed by avoiding addition of the surfactant to the polishing slurry. However, because the surfactant is not added to the polishing slurry, there is no load dependency of the polishing rate in the case of using the surfactant as described above, so that the flatness of the SiO₂ film becomes more than 100 nm, which is significantly worse than Comparison Example 1.

According to Comparison Example 4, when the foam polishing pad and the polishing slurry containing only the cerium oxide particles are used and only the dressing process is performed on the polishing pad, one of the reduction of the number of the scratches after the polishing process of the SiO₂ film and excellent flatness of the SiO₂ film cannot be obtained. Therefore, it is preferable to add the surfactant to the polishing slurry for obtaining a predetermined flatness.

In Example 1, the non-foam polishing pad is used, and after performing the dressing process and the conditioning process by injecting pure water onto the polishing pad surface, the SiO₂ film is polished. In this case, the residual cerium amount on the polishing pad becomes 0.33 at %, the number of the scratches on the SiO₂ film becomes 0.1, and the flatness of the SiO₂ film becomes less than 30 nm, which are totally excellent compared with Comparison Examples 1 to 4. Moreover, the number of the scratches at this time is within the allowable range in manufacturing the semiconductor device.

Comparing Example 1 with Comparison Examples 1 and 2, it is found that the residual cerium amount can be reduced by the process on the polishing pad in the case of the non-foam polishing pad compared with the foam polishing pad when only the dressing process is performed, however, the residual cerium amount, particularly, the agglomerated abrasive grain amount can be efficiently reduced by further performing the conditioning process of injecting pure water onto the non-foam polishing pad.

In Example 2, the non-foam polishing pad is used, and after performing the dressing process and the conditioning process by injecting a mixed fluid of pure water and nitrogen gas onto the polishing pad surface, the SiO₂ film is polished. In this case also, the residual cerium amount on the polishing pad surface, the number of the scratches on the SiO₂ film, and the flatness of the SiO₂ film similar to Example 1 can be obtained. In other words, as the conditioning agent, inert gas can be additionally mixed with a liquid such as pure water to be injected.

Comparing Example 2 with Comparison Example 3, it is considered that even when the conditioning process is performed, if the polishing pad is the foam polishing pad, it becomes difficult to remove the agglomerated abrasive grains of the polishing slurry entered into the concave portion such as the foam portion of the polishing pad. Consequently, the number of the scratches on the SiO₂ film cannot be reduced. Therefore, it is found that the use of the non-foam polishing pad is effective.

In Example 3, the non-foam polishing pad is used, and after performing the dressing process and the conditioning process by injecting an aqueous solution of the surfactant onto the polishing pad surface, the SiO₂ film is polished. In this case, while the flatness of the SiO₂ film equivalent to Examples 1 and 2 is obtained, further excellent results can be obtained in the residual cerium amount on the polishing pad surface and the number of the scratches on the SiO₂ film compared with Examples 1 and 2.

This is considered to be because the removing effect by the injection of the conditioning agent and the cleaning effect by the surfactant function in combination on the cerium particles (abrasive grains) remaining on the polishing pad surface by causing the surfactant to be contained in pure water at a concentration at which the cleaning effect is equal to or greater than the agglomeration effect and thus the residual cerium amount can be further reduced compared with Examples 1 and 2.

In Example 4, the non-foam polishing pad is used, and after performing the dressing process and the conditioning process by injecting a mixed fluid of pure water and nitrogen gas onto the polishing pad surface while rotating the polishing pad at a rotation speed higher than the case of Example 2, the SiO₂ film is polished. In this case, while the flatness of the SiO₂ film equivalent to Example 2 is obtained, further excellent results can be obtained in the residual cerium amount on the polishing pad surface and the number of the scratches on the SiO₂ film compared with Example 2.

This is considered to be because the rotation speed of the polishing table in Example 4 is set higher than the case of Example 2 and thus the centrifugal force becomes large, thereby facilitating removal of the abrasive grains on the polishing pad surface.

With the above results, a graph as shown in FIG. 5 is obtained by plotting a relationship between the residual cerium amount on the polishing pad and the number of the scratches on the SiO₂ film under the condition in which the flatness of the SiO₂ film can be suppressed to be less than 50 nm, i.e., by using the results of Examples 1 to 4 and Comparison Examples 1 to 3. FIG. 5 shows that the residual cerium amount on the polishing pad is preferably 0.35 at % or less and is particularly preferably 0.05 at % or more and 0.35 at % or less. When the residual cerium amount is more than 0.35 at %, the number of the scratches exceeds the allowable range in manufacturing the semiconductor device. Moreover, when the residual cerium amount is less than 0.05 at %, the number of the scratches on the polishing target surface can be suppressed within the allowable range in manufacturing the semiconductor device, however, this may be a factor in increasing the process cost such as a longer conditioning process time. Therefore, the residual cerium amount is preferably 0.05 at % or more in terms of reducing the process cost.

The above explained polishing method of using the non-foam polishing pad, injecting the conditioning agent onto the surface of the polishing pad at a predetermined pressure so that the average of the residual cerium amount on the surface of the polishing pad is 0.35 at % or less, and thereafter polishing the polishing target can be applied to, for example, a manufacturing method of a semiconductor device.

For example, an isolation groove with a predetermined depth is formed in a predetermined region of a silicon substrate as a semiconductor substrate, and a silicon dioxide film (SiO₂ film) is formed on the semiconductor substrate to fill this groove. Next, planarization is performed while polishing until the silicon dioxide film is removed in the region other than the inside of the groove by using the above polishing method. Whereby, an isolation insulating film in which the silicon dioxide film is buried in the groove is formed and the region isolated by this isolation insulating film becomes an element forming region. Then, a semiconductor device such as a field-effect transistor is formed in this element forming region.

As explained above, in the present embodiment, the non-foam polishing pad is used, and the polishing target is polished after performing the conditioning process of injecting the conditioning agent onto the surface of the polishing pad at a predetermined pressure so that the average of the residual cerium amount on the surface of the polishing pad is 0.35 at % or less. Whereby, the possibility that the agglomerated abrasive grains in which the cerium oxide particles are agglomerated with the surfactant remain on the polishing pad surface can be reduced. Consequently, the number of the scratches formed on the surface of the polishing target such as the silicon dioxide film on the semiconductor substrate that is polished by using the polishing pad on which the conditioning process is performed can be suppressed within the allowable range in manufacturing the semiconductor device. In other words, according to the present embodiment of the present invention, after the CMP process, high flatness of the polishing surface of the polishing target can be obtained and a defect density such as the scratches on the polishing surface of the polishing target can be reduced compared with the conventional technology.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A polishing method comprising:
performing conditioning process of injecting a conditioning agent containing liquid onto a surface of a non-foam polishing pad arranged on a polishing table at a predetermined pressure;
supplying a polishing slurry containing oxide particles and a surfactant onto the polishing pad; and
polishing a surface of a polishing target by relatively sliding the polishing target and the polishing pad; wherein
an average of a residual cerium amount is equal to or smaller than 0.35 at % when a plurality of measurement regions, each 200 μm□ in area including the surface of the polishing pad, in a cross section of the polishing pad are measured after the conditioning process.

2. The polishing method according to claim 1, wherein the conditioning agent is a mixed fluid in which the liquid is mixed with inert gas.

3. The polishing method according to claim 1, wherein the liquid is any one of pure water, a solution containing the surfactant at a concentration of 1 wt % or less, and a solution containing a hydrosoluble polymer at a concentration of 1 wt % or less.

4. The polishing method according to claim 3, wherein the surfactant includes any one of a cationic surfactant, an anionic surfactant, an amphoteric surfactant, and a nonionic surfactant.

5. The polishing method according to claim 3, wherein the surfactant is at least one compound selected from dodecylbenzenesulfonic acid and its salt.

6. The polishing method according to claim 1, wherein the conditioning process includes supplying the conditioning agent onto the polishing pad with a supply flow rate of 0.5 mL/min to 100 L/min.

7. The polishing method according to claim 1, wherein the conditioning process includes supplying the conditioning agent onto the polishing pad at a supply pressure of 500 to 5000 hPa.

8. The polishing method according to claim 1, wherein the conditioning process includes injecting the conditioning agent onto the polishing pad in a form of a mist.

9. The polishing method according to claim 1, wherein the residual cerium amount is measured by using an SEM-EDX.

10. The polishing method according to claim 1, wherein a content of the cerium oxide particles in the polishing slurry is 0.1 to 10 wt %.

11. The polishing method according to claim 1, wherein a content of the surfactant in the polishing slurry is 0.001 to 5 wt %.

12. The polishing method according to claim 1, further comprising performing a dressing process of grinding the surface of the polishing pad before the performing the conditioning process.

13. The polishing method according to claim 1, further comprising performing a dressing process of grinding the surface of the polishing pad at a same time with the performing the conditioning process.

14. The polishing method according to claim 1, further comprising performing a dressing process of grinding the surface of the polishing pad after the performing the conditioning process.

15. A manufacturing method of a semiconductor device comprising:
forming a groove having a predetermined shape on a surface of a semiconductor substrate;
forming a silicon dioxide film on the semiconductor substrate to fill the groove; and
polishing and planarizing the silicon dioxide film so that the silicon dioxide film on the semiconductor substrate other than an inside of the groove is removed by the polishing method according to claim 1.

16. A polishing apparatus comprising:
a polishing table;
a non-foam polishing pad arranged on the polishing table;
a polishing head that holds a polishing target so that a polishing target surface of the polishing target is opposed to a side of the polishing pad;
a chemical supplying unit that supplies a polishing slurry containing oxide particles and a surfactant onto the polishing pad at a time of polishing while pressing the polishing target surface of the polishing target held by the polishing head against the polishing pad and relatively sliding the polishing target held by the polishing head and the polishing table;
a dresser that grinds a surface of the polishing pad; and
a conditioning agent injecting unit that injects a conditioning agent containing liquid onto the surface of the non-foam polishing pad at a predetermined pressure.

17. The polishing apparatus according to claim 16, wherein the conditioning agent is a mixed fluid in which the liquid is mixed with inert gas.

18. The polishing apparatus according to claim 16, wherein the liquid is any one of pure water, a solution containing the surfactant at a concentration of 1 wt % or less, and a solution containing a hydrosoluble polymer at a concentration of 1 wt % or less.

19. The polishing apparatus according to claim 18, wherein the surfactant is at least one compound selected from dodecylbenzenesulfonic acid and its salt.

20. The polishing apparatus according to claim 16, wherein the conditioning agent injecting unit injects the conditioning agent onto the polishing pad in a form of a mist.
